(19) United States
(12) Patent Application Publication
(10) Pub. No.: US 2020/0255941 A1
(43) Pub. Date: Aug. 13, 2020

(54) SUPPORTS FOR CHEMICAL VAPOR DEPOSITION COATING APPLICATIONS

(71) Applicant: Kennametal Inc., Latrobe, PA (US)

(72) Inventors: Debangshu BANERJEE, Irwin, PA (US); Peter Rudolf Leicht, Latrobe, PA (US)

(21) Appl. No.: 16/271,940

(22) Filed: Feb. 11, 2019

(51) Int. Cl. C23C 16/458

(52) U.S. Cl. CPC C23C 16/4583

(57) ABSTRACT

In one aspect, carrier bodies and associated apparatus are described herein for supporting cutting tools during a CVD process. Carrier bodies and associated apparatus, in some embodiments, can facilitate proper placement and orientation of cutting tools on reactor trays while minimizing contact marks. Briefly, a carrier body comprises a base, a guide element opposite the base, and convex ridges for supporting one or more cutting tools during a chemical vapor deposition coating process.

### FIELD

The present invention relates to supports for articles being coated via chemical vapor deposition and, in particular, to supports for engaging cutting tools during chemical vapor deposition processes.

### BACKGROUND

Chemical vapor deposition (CVD) is an efficient and economical process for application of a variety of coating architectures to articles. The flexibility of CVD processes to deposit coatings of various chemistries makes it an attractive technology across a number of industries. The cutting tool industry, for example, has employed CVD processes for decades to deposit wear resistant, refractory coatings on cutting tools, including cutting inserts, end mills and drills. In order to maximize efficiencies, thousands of cutting inserts are coated in batch applications. This large number of inserts requires systematic loading and unloading logistics. In many cases, robots are employed in such loading and unloading operations. A significant disadvantage of robots is the inability to differentiate between individual insert placement positions. This can lead to placement errors and poor coating results.

Contact marks are another significant problem encountered in CVD coating processes. CVD coating, for example, is not deposited at interfaces between the article and support structure of the CVD apparatus. These uncoated regions are labeled as contact marks and can compromise coating integrity and performance. Accordingly, prior support structures have attempted to minimize contact marks. However, minimization of contact interfaces between support structures and the articles can complicate article placement and/or article orientation in the reactor, leading to coating anomalies or irregularities.

### SUMMARY

In one aspect, carrier bodies and associated apparatus are described herein for supporting cutting tools during CVD processes. Carrier bodies and associated apparatus, in some embodiments, can facilitate proper placement and orientation of cutting tools on reactor trays while minimizing contact marks. Briefly, a carrier body comprises a base, a guide element opposite the base, and convex ridges for supporting one or more cutting tools during a chemical vapor deposition coating process. In some embodiments, the convex ridges are positioned between the base and guide element and extend radially outward from a central longitudinal axis of the carrier body. Moreover, the convex ridges can define shoulders of the carrier body.

In another aspect, trays and associated carrier bodies for CVD reactors are provided. In some embodiments, a tray comprises carrier bodies for supporting cutting tools during a coating process, the carrier bodies arranged in clusters on a face of the tray. The clusters can have a periodic or aperiodic arrangement or spacing on the tray. Clusters of carrier bodies, in some embodiments, can permit spatial differentiation between the tooling placement positions on the tray, thereby facilitating proper automated loading and unloading of cutting tools. As described further herein, carrier bodies of the cluster can have any desired geometry or dimensions.

In a further aspect, carrier assemblies for tool coating processes are provided. A carrier assembly, for example, comprises a platform for engaging a tray of a chemical vapor deposition apparatus, and carrier bodies arranged on a surface of the platform, the carrier bodies having geometry for supporting cutting tools during coating application. In some embodiments, the platform comprises one or more protrusions for engaging a recess or aperture in the tray. Alternatively, the platform can have a recess or aperture for engaging a protrusion on the tray.

These and other embodiments are further described in the following detailed description.

### BRIEF DESCRIPTION OF THE DRAWINGS

FIG. 1 illustrates a front elevational view of a carrier body according to some embodiments.

FIG. 2 illustrates a perspective view of the carrier body of FIG. 1.

FIG. 3 illustrates a bottom plan view of the carrier body of FIG. 1

FIG. 4 illustrates a side elevational view of the carrier body of FIG. 1

FIGS. 5-14 illustrate various carrier body geometries and designs according to some embodiments described herein.

FIG. 15 illustrates an embodiment of a carrier assembly comprising a protrusion for inserting into a tray aperture.

### DETAILED DESCRIPTION

Embodiments described herein can be understood more readily by reference to the following detailed description and examples and their previous and following descriptions. Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

### I. Carrier Bodies

In one aspect, a carrier body comprises a base, a guide element opposite the base, and convex ridges for supporting one or more cutting tools during a coating process. The convex ridges are generally positioned between the base and guide element and extend radially outward from a central longitudinal axis of the carrier body. In some embodiments, the convex ridges define shoulders of the carrier body. The convex ridges may additionally define one or more faces of the body in conjunction with the base and/or guide element sections. Faces defined by the convex ridges may be parallel with one another, such as front and back faces. In other embodiments, faces defined by the convex ridges can intersect one another.

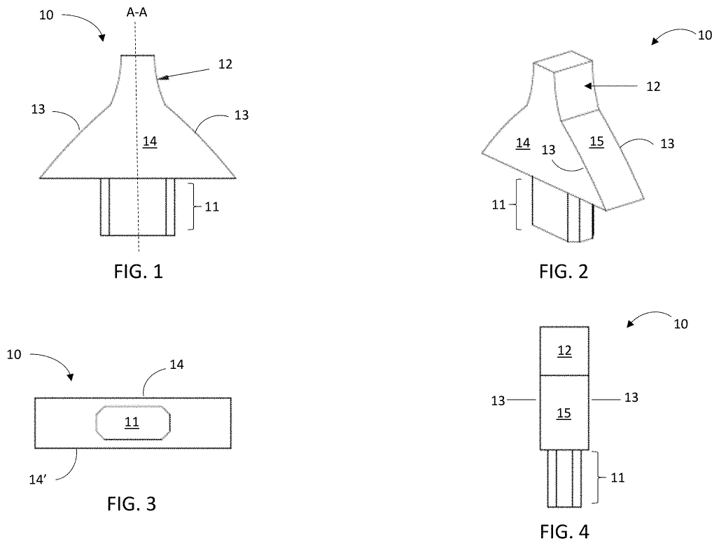

FIG. 1 illustrates a front elevational view of a carrier body according to some embodiments. As illustrated in FIG. 1, the carrier body 10 comprises a base 11 and guide element 12 opposite the base 11. Convex ridges 13 extend radially outward from a longitudinal axis A-A of the carrier body. The convex ridges 13 can extend radially outward from the longitudinal axis A-A at any desired angle. In some embodiments, the convex ridges 13 form an angle with the longitudinal axis A-A in the range of 20-80 degrees or 30-60 degrees. The convex ridges 13 define front and back faces 14, 14′ of the carrier body 10 in conjunction with the base 11 and guide element 12.

Referring now to FIG. 2, the convex ridges 13 also define shoulders 15 of the carrier body 10. In the embodiment of FIGS. 1-2, the guide element 12 extends or flows into the convex ridges 13 and associated shoulders 15. The guide element 12 can be configured to fit within an aperture of a cutting tool, such as the aperture of an indexable insert. The cutting tool is then supported by the convex ridges 13 of the carrier body 10. The convex nature of the ridges can minimize contact points between the carrier body 10 and cutting tool. The guide element 12 can have any desired shape. In some embodiments, the guide element 12 can be cylindrical or polygonal. Moreover, thickness of the guide element 12 may taper in a direction proceeding away from the convex ridges 13. The taper may be linear or curved. In the embodiment of FIGS. 1-2, the guide element 12 exhibits a concave taper.

The base 11 of the carrier body 10 can be centered along the longitudinal axis A-A. Alternatively, the base 11 can be offset from the longitudinal axis A-A. The base 11 can have any desired shape. In some embodiments, the base 11 has a polygonal cross-section. In other embodiments, the base 11 has a circular or elliptical cross-section. Shape and size of the base can be governed by several considerations including, but not limited to, engagement mechanism with a tray of a CVD reactor. The base, in some embodiments, can have shape and/or dimensions suitable for fitting within an aperture in the tray. In other embodiments, the base can have shape and/or dimensions defining an aperture for engaging a protrusion on the tray. FIG. 3 illustrates a bottom plan view of the carrier body of FIG. 1, while FIG. 4 illustrates a side elevational view. FIG. 4 details the anisotropic, flat pin shape of the carrier body 10.

Additional designs and shapes of carrier bodies are also contemplated. In some embodiments, for example, the carrier body can be pyramidal-shaped, wherein one or more edges or ridges between adjacent phases of the pyramid are convex. In some embodiments, all ridges between adjacent pyramid faces are convex. In other embodiments, a subset of the ridges can be convex. For example, a square pyramidal structure has four vertically extending ridges. Any subset of these four vertically extending ridges can be convex. Similar, a trigonal pyramidal structure has three vertically extending ridges, and any subset of these ridges can be convex. Convex ridges can be combined with straight and/or concave ridges to place the cutting tool in the proper orientation for the coating process. Combinations of convex support ridges with straight and/or concave support ridges can tilt the cutting tool, for example. In some embodiments, one or more the convex ridges in FIGS. 1-4 are replaced with a straight or concave ridge.

In additional embodiments, carrier bodies described herein do not have a base and, instead, are machined directed into a tray or platform. When machined into a tray or platform, the carrier bodies can have any desired arrangement. The carrier bodies, for example, can have a periodic or aperiodic arrangement. Moreover, the carrier bodies can be arranged in clusters as described further herein.

The carrier bodies and associated tray or platform can be fabricated of any material consistent with CVD coating operations. In some embodiments, the carrier bodies and/or tray are formed of a ceramic or refractory material. Carrier bodies, for example, can be formed of alumina or a carbide, nitride, carbonitride, oxide or oxynitride of one or more metals selected from aluminum, silicon and Groups IVB-VIB of the Periodic Table. In other embodiments, the carrier bodies and/or tray are formed of metal or alloy and subsequently coated with alumina or a carbide, nitride, carbonitride, oxide or oxynitride of one or more metals selected from aluminum, silicon and Groups IVB-VIB of the Periodic Table. In further embodiments, the carrier bodies and/or tray may be formed of graphite and/or carbon fiber composite materials.

The carrier bodies and tray can be formed of the same material or different materials. In some embodiments, for example, the carrier bodies comprise a ceramic or refractory material, and the tray comprises graphite and/or carbon fiber composite material. Any combinations of the foregoing materials for the carrier bodies and tray are contemplated herein.

### II. Trays and Carrier Assemblies for Chemical Vapor Deposition Apparatus

In another aspect, trays and associated carrier bodies and assemblies for CVD reactors are provided. In some embodiments, a tray comprises carrier bodies for supporting cutting tools during a coating process, the carrier bodies arranged in clusters on a face of the tray. The clusters can have a periodic or aperiodic arrangement or spacing on the tray. Clusters of carrier bodies, in some embodiments, can permit spatial differentiation between tooling placement locations, thereby facilitating proper automated loading and unloading of cutting tools. In some embodiments, carrier bodies vary in at least one dimension, shape, and/or spacing between the clusters.

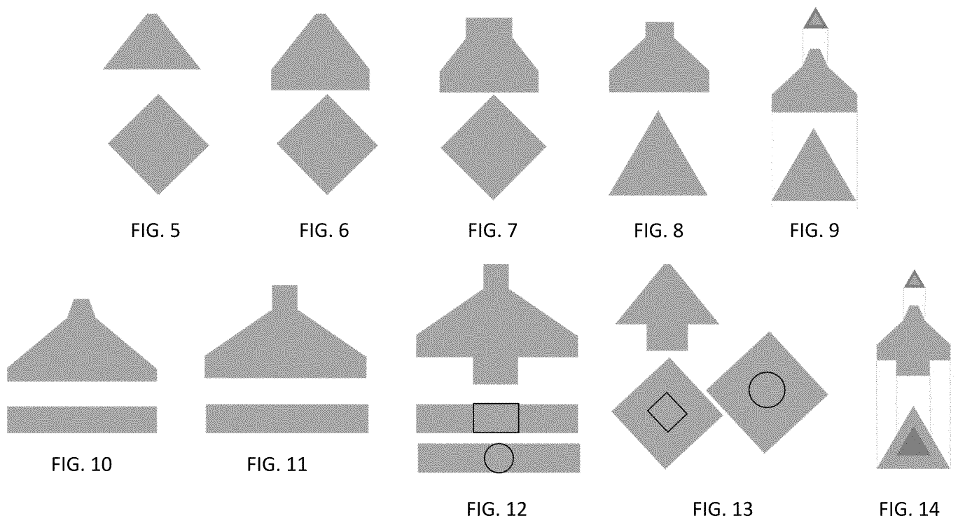

Carrier bodies of a cluster can have any shape and/or dimensions consistent with CVD coating operations for cutting tools, including indexable cutting inserts. Carrier bodies, for example, can have any properties and/or geometry described in Section I hereinabove. FIGS. 5-14 illustrate additional embodiments of carrier bodies for use in clusters described herein. The top image in each of FIGS. 5-14 is an elevational view, and the bottom image is a bottom plan view of the carrier body. In FIG. 5, for example, the carrier body comprises a trapezoidal elevational profile and a square or diamond base. For FIGS. 12-14, the polygonal and circular insets in the bottom plan views correspond to polygonal or circular protrusions for inserting into an aperture of the tray. In some embodiments, the carrier bodies of FIGS. 5-14 can exhibit one more convex ridges for engaging a cutting tool for CVD coating applications. The carrier bodies of FIGS. 5-14 can be fabricated from any material consistent with CVD coating operations. The carrier bodies of FIGS. 5-14, for example, can be formed of alumina or a carbide, nitride, carbonitride, oxide or oxynitride of one or more metals selected from aluminum, silicon and Groups IVB-VIB of the Periodic Table. In other embodiments, the carrier bodies are formed of metal or alloy and subsequently coated with alumina or a carbide, nitride, carbonitride, oxide or oxynitride of one or more metals selected from aluminum, silicon and Groups IVB-VIB of the Periodic Table. In further embodiments, the carrier bodies may be formed of graphite and/or carbon fiber composite materials.

In some embodiments, the carrier bodies are bonded to the CVD tray to provide the clusters. In other embodiments, the carrier bodies have protruding bases for inserting into apertures on the tray. Alternatively, the carrier bodies can be machined directly into the tray surface to provide the clusters. The tray can comprise the same materials as the carrier bodies. Alternatively, the tray can comprise one or more materials different from the carrier bodies.

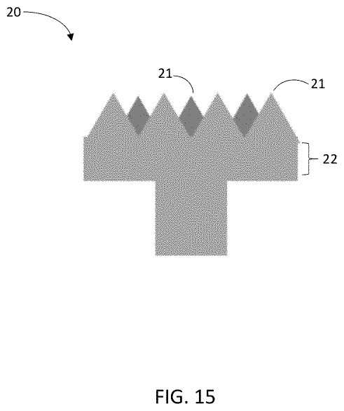

Carrier bodies can also be arranged on a platform to provide a carrier assembly. The carrier bodies can be bonded to the platform or machined into the platform. In some embodiments, the platform comprises apertures for receiving protruding bases of the carrier bodies. The platform engages or couples to the tray of a CVD reactor. The platform can have any shape including polygonal, circular or elliptical. In some embodiments, platforms of different shape and/or diameter are employed with the CVD tray to provide further spatial or optical differentiation between tooling placement locations for enhancing loading and unloading precision and accuracy. The platform comprising the carrier bodies can be simply laid on or bonded to the CVD tray in any arrangement. In other embodiments, the platform may have a protrusion for inserting into an aperture in the tray. FIG. 15 illustrates an embodiment of a carrier assembly comprising a protrusion for inserting into a tray aperture. As illustrated in FIG. 15, the carrier assembly 20 comprises carrier bodies 21 arranged on a platform 22. A protrusion 23 extends from the platform 22 for insertion into an aperture on the CVD tray. The platform and carrier bodies can be fabricated from any materials described herein including, but not limited to, alumina or other refractory materials.

CVD trays described herein may further comprise apertures between carrier bodies. The diameter and placement of the apertures can be optimized in accordance with known techniques to enable control of gas flow through the trays in the reactor.

Various embodiments of the invention have been described in fulfillment of the various objectives of the invention. It should be recognized that these embodiments are merely illustrative of the principles of the present invention. Numerous modifications and adaptations thereof will be readily apparent to those skilled in the art without departing from the spirit and scope of the invention.

1. A carrier body comprising a base, a guide element opposite the base, and convex ridges for supporting one or more cutting tools during a coating process.

2. The carrier body of claim 1, wherein the convex ridges are positioned between the base and guide element and extend radially outward from a central longitudinal axis of the carrier body.

3. The carrier body of claim 1, wherein the convex ridges define shoulders of the carrier body.

4. The carrier body of claim 1, wherein the base has a polygonal cross-section.

5. The carrier body of claim 1, wherein the base comprises a protrusion for engaging an aperture in a tray of a chemical vapor deposition apparatus.

6. The carrier body of claim 1, wherein the base comprises a recess for engaging a protrusion of a tray of a chemical vapor deposition apparatus.

7. The carrier body of claim 2, wherein one or more of the ridges form an angle with the longitudinal axis of 20 degrees to 80 degrees.

8. The carrier body of claim 3, wherein the ridges define one or more faces of the carrier body.

9. The carrier body of claim 8, wherein faces are polygonal.

10. The carrier body of claim 8, wherein two or more of the faces are parallel with one another.

11. The carrier body of claim 8, wherein carrier body comprises a front face parallel to a back face.

12. The carrier body of claim 1, wherein the guide element is configured with fit within an aperture of a cutting tool.

13. The carrier body of claim 1 formed of a composition comprising alumina, carbon fiber composite, or a carbide, nitride, carbonitride, oxide or oxynitride of one or more metals selected from aluminum, silicon and Groups IVB-VIB of the Periodic Table.

14. A tray of a chemical vapor deposition apparatus comprising:
carrier bodies for supporting cutting tools during a coating process, the carrier bodies arranged in clusters on a face of the tray.

15. The tray of claim 14, wherein the carrier bodies comprise a pyramidal base.

16. The tray of claim 14, wherein the clusters have a periodic arrangement on the tray face.

17. The tray of claim 14, wherein the clusters have an aperiodic arrangement on the tray face.

18. The tray of claim 14, wherein the carrier bodies are machined into the face of the tray.

19. The tray of claim 14, wherein the carrier bodies are bonded to the face of the tray.

20. The tray of claim 14, wherein the carrier bodies of a cluster are arranged on a platform, the platform coupled with the face of the tray.

21. The tray of claim 20, wherein the platform comprises one or more protrusions for coupling with a recess or hole in the tray.

22. The tray of claim 14, wherein the carrier bodies are formed of a composition comprising alumina, or a carbide, nitride, carbonitride, oxide or oxynitride of one or more metals selected from aluminum, silicon and Groups IVB-VIB of the Periodic Table, and the tray is formed of a composition comprising graphite and/or carbon fiber composite material.

23. A carrier assembly for cutting tool coating processes comprising:
a platform for engaging a tray of a chemical vapor deposition apparatus; and
carrier bodies arranged on a surface of the platform, the carrier bodies having geometry for supporting cutting tools during coating application.

24. The carrier assembly of claim 23, wherein the carrier bodies comprises a polygonal base.

25. The carrier assembly of claim 23, wherein the carrier bodies are pyramidal.

26. The carrier assembly of claim 23, wherein the carrier bodies are uniformly spaced on the platform.

27. The carrier assembly of claim 23, wherein the platform comprises one or more protrusions for engaging a recess or hole in the tray.

28. The carrier assembly of claim 23, wherein the carrier bodies are machined into the surface of the platform.

29. The carrier assembly of claim 23, wherein the carrier bodies and platform are each formed of a composition independently selected from the group consisting of alumina, carbon fiber composite, or a carbide, nitride, carbonitride, oxide or oxynitride of one or more metals selected from aluminum, silicon and Groups IVB-VIB of the Periodic Table.
